(19) United States
(12) Patent Application Publication
(10) Pub. No.: US 2024/0353873 A1
(43) Pub. Date: Oct. 24, 2024

(54) PUMP AND VENTILATION SYSTEM FOR VACUUM PROCESSES

(71) Applicant: VAT HOLDING AG, Haag (CH)

(72) Inventor: Wolfgang WEISS, Austria (AT)

(21) Appl. No.: 18/639,769

(22) Filed: Apr. 18, 2024

(30) Foreign Application Priority Data
Apr. 20, 2023 (DE) 10 2023 001 573.3

(51) Int. Cl. G05D 16/20; H01L 21/67

(52) U.S. Cl. CPC G05D 16/2033; H01L 21/67017

(57) ABSTRACT

A vacuum system includes at least a first vacuum valve, a second vacuum valve, a pressure sensor connected to the vacuum volume to determine an actual pressure in a vacuum volume, and a regulation and control unit connected to the first vacuum valve, to the second vacuum valve and to the pressure sensor. The regulation and control unit is configured to regulate the actual pressure based on a predetermined target pressure, with continuous detection of the actual pressure, a determination of a negative pressure or a positive pressure as the first pressure deviation based on the detected actual pressure and the predetermined target pressure, an opening of the first or the second vacuum valve to reduce the first pressure deviation, a monitoring of the first pressure deviation, a determination of a second pressure deviation, an additional opening of the other vacuum valve to reduce the second pressure deviation.

The invention relates to a system consisting of two vacuum valves, a process chamber and a control and regulation unit for the controlled and regulated operation of a processing process under vacuum conditions.

In general, vacuum valves for regulating a volume or mass flow and for essentially gas-tight closure of a flow path which leads through an opening formed in a valve housing are known from the prior art in various embodiments and are used in particular in vacuum chamber systems in the field of IC, semiconductor or substrate production, which must take place in a protected atmosphere, if possible without the presence of contaminating particles. Such vacuum chamber systems comprise, in particular, at least one evacuatable vacuum chamber provided for holding semiconductor elements or substrates to be processed or manufactured, which has at least one vacuum chamber opening through which the semiconductor elements or other substrates can be guided into and out of the vacuum chamber, as well as at least one vacuum pump for evacuating the vacuum chamber. For example, in a production system for semiconductor wafers or liquid crystal substrates, the highly sensitive semiconductor or liquid crystal elements pass sequentially through several process vacuum chambers in which the parts located within the process vacuum chambers are each processed by means of a processing device. Both during the processing process within the process vacuum chambers and during transportation from chamber to chamber, the highly sensitive semiconductor elements or substrates must always be in a protected atmosphere—in particular in an airless environment.

Peripheral valves are used to open and close a gas inlet or outlet and transfer valves are used to open and close the transfer openings of the vacuum chambers for inserting and removing the parts.

The vacuum valves through which semiconductor parts pass are referred to as vacuum transfer valves due to the area of application described and the associated dimensions, also as rectangular valves due to their mostly rectangular opening cross-section and also as slide valves, rectangular slide valves or transfer slide valves due to their usual mode of operation.

Peripheral valves are used in particular to control or regulate the gas flow between a vacuum chamber and a vacuum pump or another vacuum chamber. Peripheral valves are located, for example, within a pipe system between a process vacuum chamber or a transfer chamber and a vacuum pump, the atmosphere or another process vacuum chamber. The opening cross-section of such valves, also known as pump valves, is usually smaller than that of a vacuum transfer valve. As peripheral valves are not only used to fully open and close an opening, depending on the application, but also to control or regulate a flow by continuously adjusting the opening cross-section between a fully open position and a gas-tight closed position, they are also referred to as regulating valves. One possible peripheral valve for controlling or regulating the gas flow is the pendulum valve.

In a typical pendulum valve, as known for example from U.S. Pat. No. 6,089,537 (Olmsted), in a first step a generally round valve disk is rotationally pivoted over a generally also round opening from a position releasing the opening to an intermediate position covering the opening. In the case of a slide valve, as described for example in U.S. Pat. No. 6,416,037 (Geiser) or U.S. Pat. No. 6,056,266 (Blecha), the valve disk, like the opening, is usually rectangular and is pushed linearly in this first step from a position releasing the opening into an intermediate position covering the opening. In this intermediate position, the valve disk of the pendulum or slide valve is in a spaced-apart position opposite the valve seat surrounding the opening. In a second step, the distance between the valve disk and the valve seat is reduced so that the valve disk and the valve seat are pressed evenly against each other and the opening is essentially closed in a gas-tight manner. This second movement preferably takes place essentially in a perpendicular direction to the valve seat. Sealing can be achieved, for example, either via a sealing ring arranged on the closure side of the valve disk, which is pressed onto the valve seat surrounding the opening, or via a sealing ring on the valve seat, against which the closure side of the valve disk is pressed. Due to the two-step closing process, the sealing ring between the valve disk and the valve seat is hardly subjected to any shear forces that would destroy the sealing ring, as the movement of the valve disk in the second step is essentially in a straight line perpendicular to the valve seat.

Various sealing devices are known from the prior art, for example from U.S. Pat. No. 6,629,682 B2 (Duelli). A suitable material for sealing rings and seals in vacuum valves is, for example, fluororubber, also known as FKM, in particular the fluoroelastomer known under the trade name “Viton”, as well as perfluororubber, FFKM for short.

As the above-mentioned valves are used in the manufacture of highly sensitive semiconductor elements, among other things, the particle generation caused in particular by the actuation of the valve and the mechanical load on the valve closure member and the number of free particles in the valve chamber must be kept as low as possible. Particle generation is primarily a result of friction, for example through metal-to-metal contact and abrasion.

As described above, vacuum control valves are used to set a defined process environment in a process chamber. Regulation is typically based on a pressure signal, which provides information about the internal chamber pressure, and on a target value, i.e. a target pressure that is to be achieved by means of the regulation. The position of a valve closure (valve disk) is then varied as part of the regulation so that the target pressure is reached within a certain period of time.

As an alternative to regulation, vacuum regulating valves can also be operated in a controlled manner using known process parameters, such as a target pressure to be reached in the process chamber within a specified time. For this purpose, for example, relevant target positions are provided for the valve disk and this position is also approached at predetermined times.

Both of the above methods have their specific advantages and disadvantages. For example, a target pressure in the process chamber can be set in a relatively short time using a predefined control system, but due to a typical lack of feedback (e.g. current pressure information), a statement about the actual pressure can only be made with reservations. Any undesirable influences on the production process, such as a changed gas inlet or a leak in the process chamber, remain completely undetected and typically lead to a reduction in production quality.

In contrast to the control system, adjusting the pressure in a process chamber is more time-consuming. A feedback signal-typically generated by a pressure sensor that measures the current chamber pressure—is recorded and processed with a natural delay. Regulation based on this is therefore carried out with a corresponding delay and leads to a correspondingly later setting of the target pressure. However, the regulation of the pressure is able to set it reliably even with varying gas inlets or pressure fluctuations in the process chamber. Due to the more reliable process safety with regard to the decisive internal chamber pressure, valve regulation is preferred in most cases.

In addition, modern processing cycles require not only the provision of a specific target pressure, but also the passage through a predefined pressure curve, i.e. a desired temporal variation of the pressure in the chamber during such a cycle. For example, during a processing section for a substrate in a vacuum chamber, different pressures are required for different coating or preparation steps. Each step should be carried out at a specific pressure.

A specific pressure profile can be specified for such a process. For example, steps of such process cycles are carried out with falling pressure at different pressure levels or pressure points. For the adjustment of such a process cycle, it is therefore not only important to reach a certain chamber pressure after a certain time, but also to adjust the overall course of the pressure in the chamber accordingly or to provide different pressures during the overall course.

Known approaches for providing such pressure curves follow a regulating approach based on a pressure currently present in the chamber (actual pressure) and a target pressure to be achieved. For example, the pressure is determined for the evacuation of the chamber and compared with the target pressure. If there is a deviation such that the target pressure is lower than the actual pressure, a valve provided on the outlet side of the chamber is opened to reduce the pressure in the chamber. This valve is connected to a vacuum pump, for example.

With this regulation, the actual pressure typically falls below the target pressure on a regular basis—the pressure in the chamber is therefore initially greater than the target pressure, then less than the target pressure. When this state occurs, the valve is closed to prevent a further increase in the negative pressure. It is then preferable to wait until the chamber pressure has returned to the target pressure level. The processing process can then begin.

Due to the described (multiple) leveling of the actual pressure, the described regulation according to the prior art requires a considerable amount of time to provide the desired process conditions.

The invention is therefore based on the object of providing an improved vacuum process which is capable of overcoming the above-mentioned disadvantages.

In particular, it is the object of the invention to provide an improved vacuum system which permits improved, i.e. faster, more reliable and simpler, processing of objects.

These objects are solved by the realization of the characterizing features of the independent claims. Features which further develop the invention in an alternative or advantageous manner can be found in the dependent claims.

The basic idea of the present invention is to adapt the control or regulation of a vacuum process in such a way that improved variability with regard to the setting of the actual pressure in a process chamber can be achieved. For this purpose, it is proposed to provide a combined control of a ventilation valve (upstream) and a pump-down valve (downstream) for an evacuation or ventilation process. To achieve a desired target pressure more quickly, it should be possible to open the two valves simultaneously in a regulated and precisely controlled manner.

When venting the chamber, for example, the venting valve is first opened in order to provide a certain increase in the internal pressure of the chamber. The aim is for the pressure increase to correspond as closely as possible to a specified target pressure (e.g. target pressure curve) or to come as close as possible to it. By increasing the actual pressure, the actual pressure at a certain point in time exceeds the target pressure determined for this point in time. In contrast to the prior art, when this positive pressure condition occurs, not only is the ventilation valve closed and waited for, but the pump-down valve is also opened in addition to the ventilation valve in order to counteract the increase in pressure. This allows a target pressure to be reached more quickly. The same applies to evacuating the chamber.

In addition, this approach can also be used to create pressure curves that not only show a single direction in the pressure development, e.g. only a positive or negative gradient, but curves that alternately represent an increase in pressure and a decrease in pressure. It is therefore possible to provide a pressure profile that contains both a negative and a positive pressure change. This enables, for example, controlled particle management and controlled cleaning processes in the process chamber during a processing cycle.

Such a processing system according to the invention thus no longer provides an integrated and combined control and regulation of only one valve in isolation, but such a control and regulation unit actively regulates and controls at least one further valve and receives information from a pressure sensor. Such centralized control and regulation of several components can result in improved execution of individual process steps. As a further example, the controller can recognize when a target pressure is likely to be reached and can control the second valve before the target pressure is reached, e.g. in order to achieve a flat approximation of the actual pressure curve to the target pressure curve and to reduce overshooting or undershooting of the target pressure. This can also save a significant amount of time.

The invention thus relates to a vacuum system for processing an object. The vacuum system has at least one evacuatable vacuum volume, in particular a process chamber, having at least a first opening and a second opening. The object can be introduced into the vacuum volume for processing it.

The vacuum process volume is, for example, a process chamber that can be sealed gas-tight as required and into which the object can be inserted and removed, e.g. by means of a robot. The object can be, for example, a substrate to be coated or a wafer (semiconductor wafer).

The system also has a first vacuum valve with a first valve seat and a first valve closure, wherein the first vacuum valve is connected to the first opening and is provided for providing a first pressure change in the vacuum volume. In addition, a second vacuum valve is arranged with a second valve seat and a second valve closure, wherein the second vacuum valve is connected to the second opening and is provided for providing a second pressure change in the vacuum volume that counteracts the first pressure change.

The system also has a pressure sensor connected to the vacuum volume in such a way that the pressure sensor can be used to determine an actual pressure in the vacuum volume.

A regulation and control unit is connected to the first vacuum valve, to the second vacuum valve and to the pressure sensor. The regulation and control unit can be designed as a separate unit and have a wired or wireless communication connection with the other components.

According to the invention, the regulation and control unit is designed to regulate the actual pressure based on a predetermined target pressure for the vacuum volume, with the target pressure defining a negative pressure range and a positive pressure range. The regulation takes place in particular as part of a processing process or cycle for processing the object.

The predetermined target pressure can, for example, be specified by a user, stored on a memory unit or the regulation and control unit or provided externally, e.g. in a network or a data cloud. In particular, the predetermined target pressure can be provided as a target pressure curve (pressure curve).

As part of the regulation provided by the regulation and control unit, the actual pressure is continuously detected by the pressure sensor, a negative pressure or positive pressure is determined as the first pressure deviation based on the detected actual pressure and the predetermined target pressure, and the first or second vacuum valve is opened to change the pressure in the vacuum volume in such a way that the first pressure deviation is reduced.

If, for example, a positive pressure is detected as the first pressure deviation during a planned chamber evacuation, the valve connected to a vacuum pump can be opened.

The detection of a pressure deviation is based in particular on a comparison of the measured actual pressure with the specified target pressure. In particular, this comparison is carried out continuously during a processing cycle.

The first pressure deviation is also monitored. In particular, a reduction in the deviation, i.e. an approach of the actual pressure to the target pressure, is monitored.

In addition, a second pressure deviation is detected, which is different from the first pressure deviation. In particular, the second pressure deviation is opposite to the first pressure deviation, especially with regard to negative pressure and positive pressure. The difference in the pressure deviations can, for example, be pronounced in terms of amount, i.e. different dimensions of the deviations or different pressures, or in terms of the pressure characteristics, i.e. a negative pressure compared to a positive pressure.

There is also an additional opening of the other, in particular the second or first, vacuum valve to change the pressure in the vacuum volume in such a way that the second pressure deviation is reduced.

The simultaneous opening of both vacuum valves, i.e. the additional opening of the second valve, can actively compensate for the pressure deviation. This can be achieved in particular by generating a counter movement in relation to the pressure curve, i.e. for example active, controlled reduction of the pressure in the event of positive pressure or active, controlled increase of the pressure in the event of negative pressure.

In particular, compensation can be achieved by reducing the magnitude of the gradient of an area of an actual pressure curve.

In one embodiment, the first vacuum valve can be provided for providing a pressure increase in the vacuum volume, in particular wherein the first vacuum valve is connected to a fluid source, in particular a process gas source, and the second vacuum valve can be provided for providing a pressure reduction in the vacuum volume, in particular wherein the second vacuum valve is connected to a vacuum pump.

The first vacuum valve can accordingly be an upstream valve, i.e. a valve that is provided on the inlet side of the process chamber and can permit or regulate an inflow of fluid into the chamber. The second vacuum valve can accordingly be a downstream valve, i.e. a valve that is provided on the outlet side of the process chamber and can permit or regulate a fluid outflow from the chamber.

According to one embodiment, the regulation and control unit can have a ventilation functionality for venting the vacuum volume or for increasing the pressure in the vacuum volume. In one embodiment of the evacuation functionality, a negative pressure is detected as the first pressure deviation, the first vacuum valve is opened to increase the actual pressure, a positive pressure is subsequently detected as the second pressure deviation (in particular, the positive pressure correlating with the increase in the actual pressure) and—while the first vacuum valve is open—the second vacuum valve is opened to reduce the actual pressure.

This active control of both valves as part of a process cycle means that the target pressure can be reached quickly both when the first pressure deviation is present and when the second pressure deviation is present. The process time required to adjust the actual pressure in the chamber can be shortened accordingly.

In particular, when performing the venting functionality, a further negative pressure can be detected as a third pressure deviation—in particular wherein the further negative pressure is a consequence of the opening of the second vacuum valve—and, while the first vacuum valve is open, the second vacuum valve can be closed to increase the actual pressure or its opening can be reduced.

In one embodiment, the regulation and control unit can have an evacuation functionality for evacuating the vacuum volume or for reducing the pressure in the vacuum volume. When the evacuation functionality is implemented, a positive pressure is detected as the first pressure deviation, the second vacuum valve is opened to reduce the actual pressure, a negative pressure is subsequently detected as the second pressure deviation (in particular, the negative pressure correlating with the reduction in the actual pressure), and—while the second vacuum valve is open—the first vacuum valve is opened to increase the actual pressure.

In particular, when performing the evacuation functionality, a further positive pressure can be detected as a third pressure deviation, in particular wherein the further positive pressure is a result of the opening of the first vacuum valve, and—while the second vacuum valve is open—the first vacuum valve is closed to reduce the actual pressure or its opening (opening cross-section or mass or volume flow rate) is reduced.

In one embodiment, the regulation and control unit can have a volume cleaning functionality to provide a specific volume state. When the volume cleaning functionality is carried out
the second vacuum valve is opened to reduce the actual pressure,
a pressure drop in the vacuum volume is detected as the first pressure deviation,
while the second vacuum valve is open, the first vacuum valve is opened quickly to vent the vacuum volume intermittently, and
a relative pressure increase is detected as the second pressure deviation.

The volume cleaning functionality thus provides particle management in the volume in such a way that possible impurities can be removed from the chamber or flushed or displaced from a relevant process area of the chamber by intermittent ventilation, A relevant process area can be, for example, an area in the chamber for plasma generation.

In particular, the first vacuum valve can be opened depending on the presence of the actual pressure in a permissible venting pressure range, especially wherein the permissible venting pressure range is defined by a pressure tolerance range linked to the target pressure. The first vacuum valve is only opened when the pressure in the process chamber has already approached the target pressure to a tolerated deviation, for example.

In one embodiment, the first and/or the second vacuum valve can be designed as a vacuum control valve. Opening the first or second vacuum valve in this case involves increasing the volume or mass flow rate flowing through the vacuum valve, and/or closing the first or second vacuum valve involves reducing the volume or mass flow rate flowing through the vacuum valve.

The opening or closing of the valve is not to be understood as an exclusive state (open, closed), but rather, particularly in the context of a regulating valve, already relates to a change in this state.

In one embodiment, the target pressure can specify a time curve of the target pressure as a target pressure curve and the pressure deviation can specify a difference between the actual pressure and the target pressure provided by the target pressure curve for a specific point in time. The target pressure can be stored as a pressure curve. The desired pressure change in the vacuum volume (process chamber) can thus be represented by the pressure curve. A target pressure can thus be specified for each point in time during a process cycle. The pressure development in the process chamber should follow and correspond to this target pressure curve as precisely as possible.

In one embodiment, the target pressure can be provided by means of a target pressure curve and the target pressure curve separates the negative pressure range from the positive pressure range. A range that lies above the target pressure curve in a time-pressure diagram can be understood as a positive pressure range and a range that lies below the target pressure curve can be understood accordingly as a negative pressure range.

In one embodiment, a gradient of at least a portion of an actual pressure curve may provide the first and/or the second pressure deviation and/or the first and/or the second pressure deviation may be provided as a first and/or second actual pressure curve.

Accordingly, a first pressure deviation can differ from a second pressure deviation due to different gradients in the actual pressure curve. This applies in particular to a constant target pressure.

The invention also relates to a regulation and control unit for a vacuum system as described above. The vacuum system has at least one evacuatable vacuum volume having at least a first opening and a second opening, into which an object can be introduced for its processing. In addition, the vacuum system has a first vacuum valve with a first valve seat and a first valve closure, wherein the first vacuum valve is connected to the first opening and is provided for providing a first pressure change in the vacuum volume, and a second vacuum valve with a second valve seat and a second valve closure, wherein the second vacuum valve is connected to the second opening and is provided for providing a second pressure change in the vacuum volume that counteracts the first pressure change. The system also has a pressure sensor connected to the vacuum volume in such a way that an actual pressure in the vacuum volume can be determined using the pressure sensor.

The regulation and control unit is designed to regulate the actual pressure based on a predetermined target pressure for the vacuum volume, wherein the target pressure defines a negative pressure range and a positive pressure range. In particular, the regulation and control unit can have a correspondingly configured regulation functionality for this purpose. The regulation takes place with a continuous detection of the actual pressure by means of the pressure sensor, a determination of a negative pressure or a positive pressure as the first pressure deviation based on the detected actual pressure and the predetermined target pressure, an opening of the first or the second vacuum valve for such a pressure change in the vacuum volume that the first pressure deviation is reduced, monitoring the first pressure deviation, in particular its reduction, a determination of a second pressure deviation which is different from the first pressure deviation, in particular is opposite to the first pressure deviation (in particular with regard to negative pressure or positive pressure) and additionally opening the other vacuum valve, in particular the second or first vacuum valve, for such a pressure change in the vacuum volume that the second pressure deviation is reduced.

The invention also relates to a method for regulating the pressure in a vacuum volume (process chamber), wherein the vacuum volume has at least a first controlled closable opening and a second controlled closable opening and the method has the following steps of:
providing a predetermined target pressure, in particular a target pressure curve, wherein the target pressure defines a negative pressure range and a positive pressure range,
continuous detection of an actual pressure in the vacuum volume,
determining a negative pressure or positive pressure as the first pressure deviation based on the detected actual pressure and the predetermined target pressure,
generating—by opening the first or the second closable opening—such a pressure change in the vacuum volume that the first pressure deviation is reduced,
monitoring the first pressure deviation, in particular its reduction,
determining a second pressure deviation which is different from the first pressure deviation, in particular is opposite to the first pressure deviation, in particular with regard to negative pressure or positive pressure, and
additionally generating—by additional opening of the other closable opening, in particular the second or the first opening—such a pressure change in the vacuum volume that the second pressure deviation is reduced, in particular with the first and the second closable opening being open.

In one embodiment, the respective pressure change can be generated by means of a vacuum valve in each case, wherein a first vacuum valve is provided for providing a pressure increase in the vacuum volume, in particular wherein the first vacuum valve is connected to a fluid source, in particular a process gas source, and a second vacuum valve is provided for providing a pressure reduction in the vacuum volume, in particular wherein the second vacuum valve is connected to a vacuum pump. The vacuum volume can be vented by determining a negative pressure as the first pressure deviation, opening the first vacuum valve to increase the actual pressure, subsequently determining a positive pressure as the second pressure deviation (in particular wherein the positive pressure correlates with the increase in the actual pressure) and opening the second vacuum valve to reduce the actual pressure while the first vacuum valve is open.

In one embodiment, the respective pressure change can be generated by means of a respective vacuum valve, wherein a first vacuum valve is provided to provide an increase in pressure in the vacuum volume, in particular wherein the first vacuum valve is connected to a fluid source, in particular a process gas source, and a second vacuum valve is provided to provide a reduction in pressure in the vacuum volume, in particular wherein the second vacuum valve is connected to a vacuum pump. The vacuum volume can be evacuated by detecting a positive pressure as the first pressure deviation, opening the second vacuum valve to reduce the actual pressure, subsequently detecting a negative pressure as the second pressure deviation (in particular where the negative pressure correlates with the reduction in the actual pressure), and opening the first vacuum valve to increase the actual pressure while the second vacuum valve is open.

The invention further relates to a computer program product which is stored on a machine-readable carrier, in particular stored in an above-mentioned regulation and control unit, comprising program code for carrying out or controlling at least the following steps of the above method:
continuous detection of an actual pressure in the vacuum volume,
determining a negative pressure or a positive pressure as the first pressure deviation based on the detected actual pressure and a predetermined target pressure,
opening of the first or second closable opening to generate such a pressure change in the vacuum volume that the first pressure deviation is reduced,
monitoring the first pressure deviation,
determining a second pressure deviation which is different from the first pressure deviation, and
additional opening of the other closable opening to generate such a pressure change in the vacuum volume that the second pressure deviation is reduced.

In particular, the program or program code is executed in an electronic data processing unit, in particular the regulation and control unit, of the vacuum system or in the regulation and control unit. It is therefore possible to control and regulate an (entire) process cycle by executing a corresponding (computer-implemented) algorithm.

The device according to the invention and the method according to the invention are described in more detail below purely by way of example with reference to specific exemplary embodiments shown schematically in the drawings, and further advantages of the invention are also discussed, which drawings show as follows:

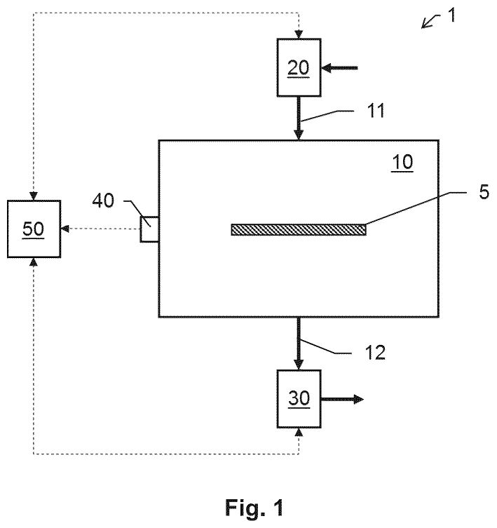

FIG. 1 shows a schematic representation of a first embodiment of a vacuum system for the controlled-regulated operation of a process cycle according to the invention;

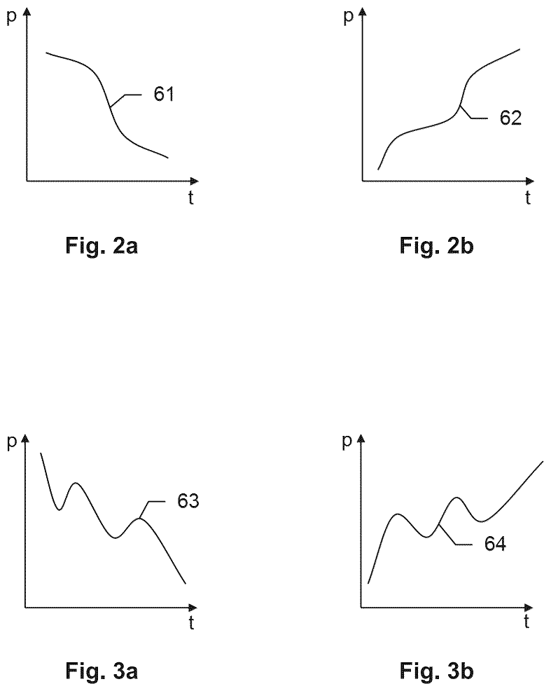

FIGS. 2a-b show two exemplary pressure provides in the evacuation and ventilation according to the prior art;

FIGS. 3a-b show two exemplary pressure profiles according to the invention for evacuation and ventilation; and

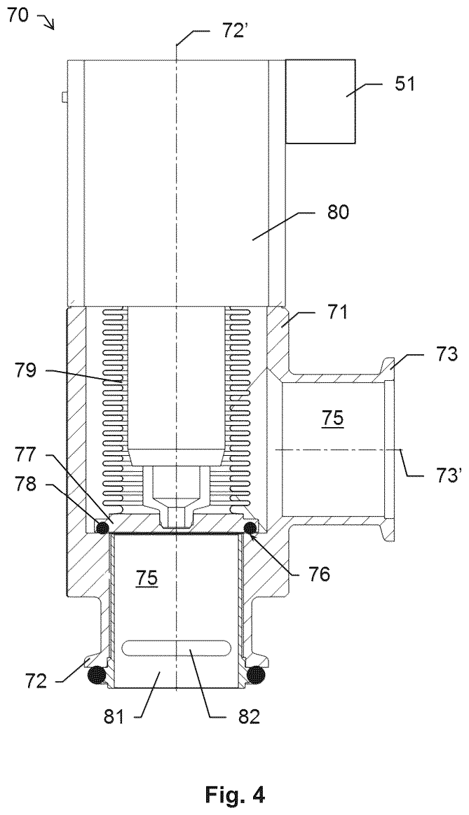

FIG. 4 shows an exemplary embodiment of a vacuum regulating valve.

FIG. 1 schematically shows a structure of a vacuum system 1 according to the invention for processing an object 5, e.g. a semiconductor wafer, under vacuum conditions. The structure has a vacuum volume 10 (vacuum process chamber), a first vacuum valve 20 and a second vacuum valve 30. An inlet line 11 connects the process chamber 10 to the first vacuum valve 20 and an outlet line 12 connects the process chamber 10 to the second vacuum valve 30.

In this embodiment, the first vacuum valve 20 is provided as an (upstream) ventilation valve and provides a mass or volume inflow of a fluid into the chamber 10 when the valve 20 is opened. The vacuum valve 20 is designed as a regulating valve and thus enables a controlled setting of an opening cross-section and thus the setting of a quantity of fluid flowing through the valve 20 per time unit. The fluid can be a process gas, a precursor gas or an (inert) gas used to flush the chamber 10, for example. The fluid source can be provided as a tank or with a mass flow controller (MFC).

In this embodiment, the second vacuum valve 30 is provided as a (downstream) evacuation valve and provides a mass or volume outflow of a fluid from the chamber when the valve 30 is opened. The vacuum valve 30 is also designed as a regulating valve and thus also enables a controlled setting of an opening cross-section and thus the setting of a quantity of fluid flowing through the valve 30 per unit of time. In addition to the connection to the volume 10, the second vacuum valve 30 is preferably connected to a vacuum pump and thus provides for pumping fluid out of the volume 10.

Compared to a simpler “on/off” valve, a vacuum regulating valve offers the advantage that the respective flows can be set very precisely by such a valve. In conjunction with the present invention, this can provide further improved regulation of the internal chamber pressure.

The vacuum system 1 also has a pressure sensor 40. The pressure sensor 40 is connected to the vacuum volume 10 in such a way that the current actual pressure in the vacuum volume 10 can be determined by means of the sensor 40.

The vacuum system 1 also has a regulation and control unit 50. The regulation and control unit 50 is connected to the pressure sensor 40, the first vacuum valve 20 and the second vacuum valve 30.

The connection with the pressure sensor 40 is preferably monodirectional, i.e. the regulation and control unit 50 receives the pressure information provided by the pressure sensor 40. The connections with the two valves 20 and 30, on the other hand, can be monodirectional or bidirectional, i.e. the valves 20 and 30 receive signals for controlling and changing the valve opening on the one hand, and on the other hand the connections can be designed so that the regulation and control unit 50 receives information from the respective valve, in particular information about an opening state.

According to the invention, the regulation and control unit is designed to regulate the actual pressure based on a predetermined target pressure for the vacuum volume. The predetermined target pressure defines a negative pressure range and a positive pressure range. The regulation of the actual pressure relates in particular to the regulation or control of the pressure in the vacuum volume for a processing process. The regulation and control unit 50 has a correspondingly configured regulation functionality for this purpose. The regulation functionality can be realized in particular as an algorithm or computer-implemented method.

The actual pressure is regulated by continuously recording the actual pressure using the pressure sensor and determining a negative pressure or a positive pressure as the first pressure deviation based on the recorded actual pressure and the predetermined target pressure. The negative pressure or positive pressure is determined in particular by comparing a currently measured actual pressure and a target pressure specified for the relevant processing step or point in time.

The first or second vacuum valve is then opened to change the pressure in the vacuum volume in such a way that the first pressure deviation is reduced. If, for example, a positive pressure is detected, the evacuation valve 30 is opened. The first pressure deviation, in particular its reduction, is further monitored.

As a result, a second pressure deviation is determined which is opposite to the first pressure deviation, in particular is opposite with respect to negative pressure or positive pressure. In the context of the present invention, an opposing pressure deviation can also be understood as a part of a pressure curve whose direction (gradient of the curve) is different from a direction of another part of a pressure curve.

The other, in particular the second or first, vacuum valve is then additionally opened to change the pressure in the vacuum volume in such a way that the second pressure deviation is reduced. If, for example, a negative pressure is detected as the second pressure deviation, the ventilation valve 20 can be opened in addition to the evacuation valve 30 to reduce the negative pressure.

FIGS. 2a and 2b each show a regulated pressure curve of the actual pressure in a vacuum chamber according to the prior art. On the one hand, regulating valves are already provided here in order to meet the requirements of the pumping and venting cycles. However, only either negative profiles for a pumping cycle (FIG. 2a) or positive profiles for a venting cycle (FIG. 2b) can be realized with previously known arrangements. In this context, a negative profile should be understood as a pressure curve 61 whose gradient (direction) can vary but remains negative throughout. The same applies to a positive profile with a positive gradient of the pressure curve 62.

FIGS. 3a and 3b each show a regulated pressure curve of the actual pressure in a vacuum chamber according to the invention.

By the combined activation of the first vacuum valve and the second vacuum valve described above, negative and positive target curve sections can be generated in each cycle. The respective pressure curves 63, 64 are no longer purely negative or positive, but can each have curve sections with a negative gradient and curve sections with a positive gradient. Such pressure profiles allow, for example, controlled particle management and controlled cleaning of the vacuum volume. For example, as part of a chamber evacuation (negative gradient of the pressure curve), excess and unwanted particles can be flushed out by intermediate ventilation (positive gradient of the pressure curve). This can result in a pressure curve as shown in FIG. 3a.

A further advantage of the regulation of the vacuum system according to the invention is that exceeding and falling below a predetermined target curve (target pressure or target pressure curve) can be compensated for comparatively much faster. This can be achieved by actively counteracting a pressure deviation by additionally opening the second valve. Such active compensation of positive pressure or negative pressure results in faster process cycles and shorter cycle times.

FIG. 4 shows an embodiment of a vacuum valve 70. The vacuum valve 70 is designed here as an angle regulating valve 70. Such an angle regulating valve 70 can be provided in particular as a first and/or second vacuum valve 20, 30 of a system according to FIG. 1. It should be understood, however, that the angle regulating valve 70 shown represents only one specific embodiment of a vacuum valve and that alternative vacuum valve types may also or alternatively be provided in the vacuum system according to the invention.

The angle valve 70 has a valve housing 71 with a first connection 72 and a second connection 73. The connections 72, 73 are essentially orthogonal to each other. The first connection 72 correspondingly defines a first axis 72′ and the second connection 73 a second axis 73′, wherein these axes 72′, 73′ are also correspondingly orthogonal relative to one another. An axis intersection point is located inside the housing 71.

The two connections 72,73 define a flow path for a medium or fluid (e.g. process gas). The flow path extends through a flow chamber 75, which connects the two connections 72, 73. The flow path can be interrupted or released by means of the valve 70.

The valve has a drive unit 80. In particular, the drive unit 70 has a controllable electric motor, the drive shaft of which is structurally connected to a valve closure 77 (valve disk) of the valve 70 by means of a drive mechanism (gear). The drive unit 80 in the embodiment shown has a spindle drive with a threaded rod and a guide element which interacts with the threaded rod and can be moved along the axis 72′ by rotating the threaded rod. The guide element is coupled to the valve disk 77.

The movable valve disk 77 is arranged inside the valve housing 71. The valve disk 77 has a sealing surface with a circumferentially arranged sealing material 78, by means of which a gas-tight interruption of the flow path can be provided when contact is made with a valve seat 76 on the housing side. The valve disk 77 can be shaped like a piston, for example. The sealing material can, for example, have an O-ring made of fluoropolymer or a vulcanized seal.

The valve 70 also has a bellows 79. The bellows 79 is connected on the one hand to the valve disk 77 and on the other hand to an inner housing part of the valve 70. The bellows 79 can be designed as a metallic corrugated bellows or concertina bellows. The bellows 79 provides atmospheric separation of at least parts of the drive unit (e.g. threaded rod) and the flow chamber 75. This can prevent particles generated on the drive side from entering the flow chamber 75.

The valve 70 also has a regulation and control unit 51 for controlling the displacement of the valve disk 77. The regulation and control unit 51 is connected to the electric motor to control it. The regulation and control unit 51 can also provide the regulation and control unit 50 of the vacuum system.

The regulation and control unit 51 can accordingly be of integrated design with the vacuum valve 70, i.e. the regulation and control unit is provided by and with the valve and further system components which are to be actuated or read out with the regulation and control unit, in particular a pressure sensor and a further vacuum valve, are connected to the valve or its regulation and control unit.

In the embodiment shown, the vacuum valve 70 further comprises a sleeve 81 with a sleeve recess 82 in the sleeve wall. However, the invention also relates to alternative embodiments without such a sleeve 81.

It is understood that the figures shown only schematically represent possible exemplary embodiments. According to the invention, the various approaches can also be combined with each other and with methods and devices for pressure regulation or control for and of vacuum processes of the prior art.

1. A vacuum system for processing an object, comprising at least:
an evacuatable vacuum volume with at least a first opening and a second opening, into which vacuum volume the object can be introduced for its processing,
a first vacuum valve having a first valve seat and a first valve closure, wherein the first vacuum valve is connected to the first opening and is provided for providing a first pressure change in the vacuum volume,
a second vacuum valve having a second valve seat and a second valve closure, wherein the second vacuum valve is connected to the second opening and is provided for providing a second pressure change in the vacuum volume which counteracts the first pressure change,
a pressure sensor connected to the vacuum volume in such a way that an actual pressure in the vacuum volume can be determined with the pressure sensor,
and
a regulation and control unit, which is connected to the first vacuum valve, to the second vacuum valve and to the pressure sensor,
wherein
the regulation and control unit is designed to regulate the actual pressure based on a target pressure predetermined for the vacuum volume, wherein the target pressure defines a negative pressure range and a positive pressure range, with
a continuous detection of the actual pressure by means of the pressure sensor,
a determination of negative pressure or positive pressure as the first pressure deviation based on the detected actual pressure and the predetermined target pressure,
an opening of the first or second vacuum valve for such a pressure change in the vacuum volume that the first pressure deviation is reduced,
a monitoring of the first pressure deviation,
a determination of a second pressure deviation which is different from the first pressure deviation, opposite to the first pressure deviation, and
an additional opening of the other, vacuum valve for such a pressure change in pressure in the vacuum volume that the second pressure deviation is reduced.

2. The vacuum system according to claim 1,
wherein
the first vacuum valve is provided for providing a pressure increase in the vacuum volume, wherein the first vacuum valve is connected to a fluid source, and
the second vacuum valve is provided for providing a pressure reduction in the vacuum volume, wherein the second vacuum valve is connected to a vacuum pump.

3. The vacuum system according to claim 2, wherein
the regulation and control unit has a ventilation functionality for venting the vacuum volume or for increasing the pressure in the vacuum volume, wherein when performing the evacuation functionality
a negative pressure is determined as the first pressure deviation,
the first vacuum valve is opened to increase the actual pressure,
subsequently a positive pressure is detected as the second pressure deviation, wherein the positive pressure correlates with the increase in the actual pressure, and
while the first vacuum valve is open, the second vacuum valve is opened to reduce the actual pressure.

4. The vacuum system according to claim 3, wherein when performing the ventilation functionality
a further negative pressure is determined as a third pressure deviation, wherein the further negative pressure is a consequence of the opening of the second vacuum valve, and
while the first vacuum valve is open, the opening of the second vacuum valve is reduced to increase the actual pressure or the second vacuum valve is closed.

5. The vacuum system according to claim 2, wherein the regulation and control unit has an evacuation functionality for evacuating the vacuum volume or for reducing the pressure in the vacuum volume, wherein when performing the evacuation functionality
a positive pressure is detected as the first pressure deviation,
the second vacuum valve is opened to reduce the actual pressure,
subsequently a negative pressure is detected as the second pressure deviation, wherein the negative pressure correlates with the reduction in the actual pressure,
while the second vacuum valve is open, the first vacuum valve is opened to increase the actual pressure.

6. The vacuum system according to claim 5, wherein when performing the evacuation functionality
a further positive pressure is determined as a third pressure deviation, wherein the further positive pressure is a consequence of the opening of the first vacuum valve, and
while the second vacuum valve is open, the opening of the first vacuum valve is reduced to reduce the actual pressure or the first vacuum valve is closed.

7. The vacuum system according to claim 1, wherein the regulation and control unit has a volume cleaning functionality for providing a specific volume state, wherein in the performance thereof
the second vacuum valve is opened to reduce the actual pressure,
a pressure drop in the vacuum volume is detected as the first pressure deviation,
while the second vacuum valve is open, the first vacuum valve is opened quickly to ventilate the vacuum volume intermittently,
a relative pressure increase is detected as the second pressure deviation.

8. The vacuum system according to claim 7, wherein the opening of the first vacuum valve takes place as a function of the presence of the actual pressure in a permissible venting pressure range, wherein the permissible venting pressure range is defined by a pressure tolerance range linked to the target pressure.

9. The vacuum system according to claim 1, wherein the first and/or the second vacuum valve is designed as a vacuum regulating valve, wherein
the opening of the first or second vacuum valve comprises an increase in the volume or mass flow rate flowing through the vacuum valve, and/or
the closing of the first or second vacuum valve comprises a reduction in the volume or mass flow rate flowing through the vacuum valve.

10. The vacuum system according to claim 1, wherein
the target pressure indicates a time curve of the target pressure as a target pressure curve and
the pressure deviation indicates a difference between the actual pressure and the target pressure provided by the target pressure curve for a specific point in time.

11. The vacuum system according to claim 1, wherein the target pressure is provided by means of a target pressure curve and the target pressure curve separates the negative pressure range from the positive pressure range.

12. The vacuum system according to claim 1, wherein
a gradient of at least a part of an actual pressure curve provides the first and/or the second pressure deviation and/or
the first and/or second pressure deviation is provided as a first and/or second actual pressure curve.

13. A regulation and control unit for a vacuum system according to claim 1, wherein the vacuum system comprises at least
an evacuatable vacuum volume with at least a first opening and a second opening, into which an object can be introduced for its processing,
a first vacuum valve having a first valve seat and a first valve closure, wherein the first vacuum valve is connected to the first opening and is provided for providing a first pressure change in the vacuum volume,
a second vacuum valve having a second valve seat and a second valve closure, wherein the second vacuum valve is connected to the second opening and is provided for providing a second pressure change in the vacuum volume which counteracts the first pressure change, and
a pressure sensor connected to the vacuum volume in such a way that an actual pressure in the vacuum volume can be determined with the pressure sensor,
wherein
the regulation and control unit is designed to regulate the actual pressure based on a target pressure predetermined for the vacuum volume, wherein the target pressure defines a negative pressure range and a positive pressure range, wherein the regulation and control unit has a correspondingly configured regulating functionality, with
continuous detection of the actual pressure by means of the pressure sensor,
a determination of negative pressure or positive pressure as the first pressure deviation based on the detected actual pressure and the predetermined target pressure,
an opening of the first or second vacuum valve for such a pressure change in the vacuum volume that the first pressure deviation is reduced,
a monitoring of the first pressure deviation,
a determination of a second pressure deviation which is different from the first pressure deviation, is opposite to the first pressure deviation, with regard to negative pressure or positive pressure, and
an additional opening of the other, vacuum valve for such a pressure change in the vacuum volume that the second pressure deviation is reduced.

14. A method for regulating pressure in a vacuum volume, wherein the vacuum volume has at least a first closable opening and a second closable opening, the method comprising the steps of:
providing a predetermined target pressure, wherein the target pressure defines a negative pressure range and a positive pressure range,
continuous detection of an actual pressure in the vacuum volume,
determining a negative pressure or positive pressure as the first pressure deviation based on the detected actual pressure and the predetermined target pressure,
generating—by opening the first or the second closable opening—such a pressure change in the vacuum volume that the first pressure deviation is reduced,
monitoring the first pressure deviation,
determining a second pressure deviation which is different from the first pressure deviation, is opposite to the first pressure deviation, with regard to negative pressure or positive pressure, and
additionally generating—by additional opening of the other closable opening, in particular the second or the first opening—of such a pressure change in the vacuum volume that the second pressure deviation is reduced, with the first and the second closable opening being open.

15. The method according to claim 14, wherein
the respective pressure change is generated by means of a respective vacuum valve in each case, wherein
a first vacuum valve is provided for providing a pressure increase in the vacuum volume, wherein the first vacuum valve is connected to a fluid source,
a second vacuum valve is provided for providing a pressure reduction in the vacuum volume, wherein the second vacuum valve is connected to a vacuum pump, and
venting of the vacuum volume is carried out by
determining negative pressure as the first pressure deviation,
opening the first vacuum valve to increase the actual pressure,
subsequently determining a positive pressure as the second pressure deviation, wherein the positive pressure correlates with the increase of the actual pressure, and
opening the second vacuum valve to reduce the actual pressure while the first vacuum valve is open.

16. The method according to claim 14, wherein
the respective pressure change is generated by means of a respective vacuum valve in each case, wherein
a first vacuum valve is provided for providing a pressure increase in the vacuum volume, wherein the first vacuum valve is connected to a fluid source,
a second vacuum valve is provided for providing a pressure reduction in the vacuum volume, wherein the second vacuum valve is connected to a vacuum pump, and
evacuation of the vacuum volume is carried out by
determining a positive pressure as the first pressure deviation,
opening the second vacuum valve to reduce the actual pressure,
subsequently determining a negative pressure as the second pressure deviation, wherein the negative pressure correlates with the reduction of the actual pressure, and
opening the first vacuum valve to increase the actual pressure while the second vacuum valve is open.

17. A computer program product which is stored on a machine-readable carrier, stored in a regulation and control unit according to claim 1, comprising program code for carrying out or controlling at least the following steps of the method according to claim 14:
continuous detection of an actual pressure in the vacuum volume,
determining a negative pressure or positive pressure as the first pressure deviation based on the actual pressure detected and a predetermined target pressure,
opening the first or the second closable opening to generate such a pressure change in the vacuum volume that the first pressure deviation is reduced,
monitoring the first pressure deviation,
determining a second pressure deviation which is different from the first pressure deviation, and
an additional opening of the other closable opening to generate such a pressure change in the vacuum volume that the second pressure deviation is reduced.
